(19) United States
(12) Patent Application Publication
(10) Pub. No.: US 2018/0286710 A1
(43) Pub. Date: Oct. 4, 2018

(54) CERAMIC HEATER

(71) Applicant: Mico Co., Ltd., Anseong-si (KR)

(72) Inventors: Chul Ho JUNG, Anseong-si (KR); Jin Young CHOI, Anseong-si (KR); Ju Sung LEE, Daejeon (KR)

(73) Assignee: Mico Co., Ltd., Anseong-si (KR)

(21) Appl. No.: 15/942,699

(22) Filed: Apr. 2, 2018

(30) Foreign Application Priority Data
Apr. 3, 2017 (KR) 10-2017-0042856

(51) Int. Cl. H01L 21/67; H01L 21/683; H01L 21/687; H01J 37/32; C23C 16/46

(52) U.S. Cl. CPC H01L 21/67103; H01L 21/6833; H01L 21/68742; H01L 21/6875; C23C 16/513; C23C 16/46; H01J 2237/3323; H01J 2237/3321; H01J 37/32724

(57) ABSTRACT

A ceramic heater includes a ceramic body having a plurality of pin holes for a vertical movement of lift pins, a heating member disposed inside the ceramic body to heat a wafer which is placed on the ceramic body, and heat transfer members disposed on an upper surface of the ceramic body to surround upper portions of the pin holes, respectively. The pin holes are configured to pass through the ceramic body and the heat transfer members are used to transfer heat generated from the heating member to the wafer so as to uniformly heat the wafer.

### CROSS-REFERENCE TO RELATED APPLICATION

This application claims the priority benefit of Korean Patent Application No. 10-2017-0042856 filed on Apr. 3, 2017, and all the benefits accruing therefrom under 35 U.S.C. § 119, the contents of which are incorporated by reference in their entirety.

### BACKGROUND

The present disclosure relates to a ceramic heater. More specifically, the present disclosure relates to a ceramic heater for heating a wafer in a semiconductor manufacturing process.

In general, semiconductor devices may be formed on a silicon wafer used as a semiconductor substrate by repeatedly performing a series of manufacturing processes, and the semiconductor devices formed as described above may be formed into semiconductor packages through a dicing process, a bonding process, and a packaging process.

For example, various layer such as an insulating layer, a conductive layer and the like may be formed on the wafer through a deposition process such as a physical vapor deposition process, a chemical vapor deposition process, a plasma enhanced chemical vapor deposition process and the like.

Particularly, In the case of a plasma enhanced chemical vapor deposition process, the wafer may be heated to a process temperature and a desired layer may be formed on the wafer by reaction between a source gas and a reactive gas formed in a plasma state.

An apparatus for performing the plasma enhanced chemical vapor deposition process may include a plasma source for forming a source gas and a reactive gas supplied into a process chamber in a plasma state, and a ceramic heater for supporting the wafer and heating the wafer to a process temperature.

The ceramic heater may include a heating member for heating the wafer to the process temperature and an electrode member for forming the source gas and the reactive gas in the plasma stage. Further, the ceramic heater may have a plurality of pin holes for a vertical movement of lift pins. The heating member and the electrode member may be disposed inside a ceramic body, and the pin holes may be configured to pass through the ceramic body.

Particularly, the heating member may be disposed apart from the pin holes, and upper portions of the pin holes may have a structure in which a cross-sectional area increases upward. Thus, the heat generated from the heating member may be not uniformly transferred to the wafer supported on the ceramic body. That is, temperatures of portions of the wafer located over the pin holes may be lower those of the remaining portions.

When the deposition process is performed in a stage which the wafer is not uniformly heated as described above, a thickness of a layer formed on the wafer may not be uniform. That is, the thickness of portions of the layer formed over the pin holes may be relatively thin compared to the remaining portions.

### SUMMARY

The present disclosure provides a ceramic heater capable of uniformly heating a wafer.

In accordance with some exemplary embodiments of the present disclosure, a ceramic heater may include a ceramic body having a plurality of pin holes for a vertical movement of lift pins, a heating member disposed inside the ceramic body to heat a wafer which is placed on the ceramic body, and heat transfer members disposed on an upper surface of the ceramic body to surround upper portions of the pin holes, respectively. The pin holes may be configured to pass through the ceramic body and the heat transfer members may be used to transfer heat generated from the heating member so as to the wafer to uniformly heat the wafer.

In accordance with some exemplary embodiments of the present disclosure, the heat transfer members may be made of the same material as the ceramic body or a material having a heat transfer rate higher than the ceramic body.

In accordance with some exemplary embodiments of the present disclosure, the heat transfer members may have a ring shape configured to surround the upper portions of the pin holes, respectively.

In accordance with some exemplary embodiments of the present disclosure, each of the heat transfer members may include a plurality of parts disposed to be spaced apart from each other around the respective pin holes.

In accordance with some exemplary embodiments of the present disclosure, the heat transfer members may be disposed in close contact with the pin holes or spaced apart from the pin holes.

In accordance with some exemplary embodiments of the present disclosure, a distance between each of the heat transfer members and each of the pin holes may be 0 to approximately 20 mm.

In accordance with some exemplary embodiments of the present disclosure, an upper surface area of each of the heat transfer members may be approximately 13 mm² to approximately 1900 mm².

In accordance with some exemplary embodiments of the present disclosure, the ceramic heater may further include a plurality of support members disposed on the upper surface of the ceramic body to support the wafer.

In accordance with some exemplary embodiments of the present disclosure, the heat transfer members may have the same height as the support members.

In accordance with some exemplary embodiments of the present disclosure, the height of the heat transfer members may be approximately 5 μm to approximately 40 μm.

In accordance with some exemplary embodiments of the present disclosure, the ceramic heater may further include an electrode member disposed inside the ceramic body and electrically connected with an external ground member.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Exemplary embodiments can be understood in more detail from the following description taken in conjunction with the accompanying drawings, in which:

FIG. 1 is a partial cross-sectional view illustrating a ceramic heater in accordance with an exemplary embodiment of the present disclosure;

FIG. 2 is a plan view illustrating the ceramic heater as shown in FIG. 1;

FIG. 3 is a plan view illustrating some examples of the heat transfer members as shown in FIG. 1; and

FIG. 4 is a plan view illustrating other examples of the heat transfer members as shown in FIG. 1.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

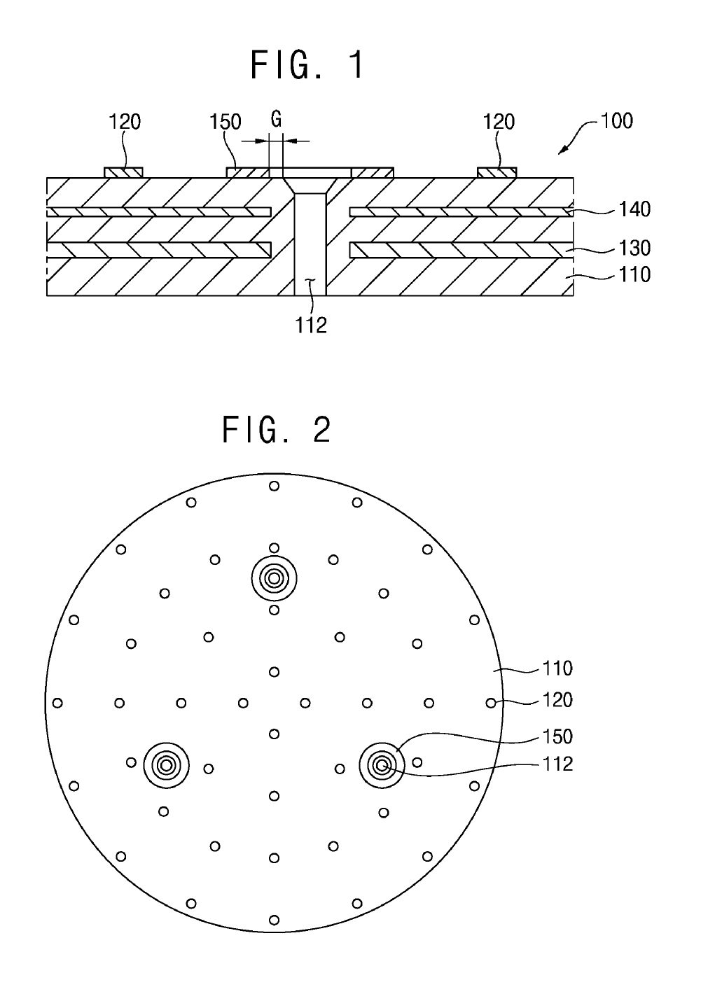

FIG. 1 is a partial cross-sectional view illustrating a ceramic heater in accordance with an exemplary embodiment of the present disclosure, and FIG. 2 is a plan view illustrating the ceramic heater as shown in FIG. 1.

Referring to FIGS. 1 and 2, a ceramic heater 100, in accordance with an exemplary embodiment of the present disclosure, may include a ceramic body 110, support members 120, a heating member 130, an electrode member 140 and heat transfer members 150.

The ceramic body 110 may have a flat plate shape and may be made of a ceramic material. The ceramic material is excellent in heat resistance and is an electrical insulator. For example, the ceramic body 110 may be made of Al₂O₃, Y₂O₃, Al₂O₃/Y₂O₃, ZrO₂, AlC (Autoclaved lightweight concrete), TiN, AlN, TiC, MgO, CaO, CeO₂, TiO₂, BxCy, BN, SiO₂, SiC, YAG, Mullite, AlF₃, and the like.

The ceramic body 110 may have a plurality of pin holes 112 for a vertical movement of lift pins (not shown). The pin holes 112 may be formed to pass through the ceramic body 110. The lift pins may vertically move through the pin holes 112 to load a wafer (not shown) onto an upper surface of the ceramic body 110 or to unload the wafer from the upper surface of the ceramic body 110.

On the other hand, upper portions of the pin holes 112 may have a structure in which a cross-sectional area increases upward.

The support members 120 may be used to support the wafer and may be disposed on the upper surface of the ceramic body 110 to be spaced apart from each other. The support members 120 may be concentrically or radially arranged with respect to a center of the upper surface of the ceramic body 110. The support members 120 may horizontally and stably support the wafer even if a flatness of the upper surface of the ceramic body 110 is poor. The wafer may be spaced apart from the upper surface of the ceramic body 110 by the support members 120. Thus, the wafer may be prevented from being brought into close contact with ceramic body 110.

The support members 120 may be made of the same material as the ceramic body 110. In such case, the support members 120 may be integrally formed with the ceramic body 110. Alternatively, after the support members 120 are separately prepared, the support members 120 may be assembled to the ceramic body 110.

Meanwhile, the support members 120 may be made of a material different from that of the ceramic body 110. In this case, the support members 120 and the ceramic body 110 may be formed separately.

The heating member 130 may be disposed inside the ceramic body 110. For example, the heating member 130 may have a disc shape smaller than the ceramic body 110. At this time, the heating member 130 may have openings corresponding to the pin holes 112. The heating member 130 may be connected with an external power supply (not shown), and may generate heat for heating the wafer placed on the support members 120.

The heating member 130 may be made of a metal material capable of generating heat. For example, the heating member 130 may be formed of tantalum (Ta), nickel (Ni), tungsten (W), molybdenum (Mo), silver (Ag), gold (Au), niobium (Nb), titanium (Ti) or an alloy thereof.

The electrode member 140 may be disposed inside the ceramic body 110. For example, the electrode member 140 may have a disc shape smaller than the ceramic body 110. At this time, the electrode member 140 may have openings corresponding to the pin holes 112. The electrode member 140 may be disposed at a different height from the heating member 130. For example, the electrode member 140 may be disposed over the heating member 130 or may be disposed below the heating member 130. The electrode member 140 may be electrically connected to an external ground member. The electrode member 140 may be made of a metal having excellent conductivity. For example, the electrode member 140 may be made of a material similar to the heating member 130, and may be used to provide a reference voltage for forming a source gas and a reactive gas in a plasma state in a plasma enhanced chemical vapor deposition process.

The heating member 130 and the electrode member 140 may be configured to be spaced apart from the pin holes 112 so as to prevent contact with the lift pins. That is, the openings of the heating member 130 and the electrode member 140 may have inner diameters greater than those of the pin holes 112.

The heat transfer members 150 may be disposed on the upper surface of the ceramic body 110 to surround the upper portions of the pin holes 112. The heat transfer members 150 may support the wafer and may be used to transfer the heat generated from the heating member 130. Thus, even if the heating member 130 is spaced apart from the pin holes 112 and the upper portions of the pin holes 112 have a structure in which a cross-sectional area increases upward, the heat generated from the heating member 130 may be directly transferred to the portions of the wafer located over the pin holes 112 through the heat transfer members 150. Consequently, the wafer may be uniformly heated by the heating member 130, and thus a layer may be uniformly formed on the wafer during the deposition process.

The heat transfer members 150 may be made of a ceramic material. For example, the heat transfer members 150 may be made of a ceramic material having a heat transfer rate higher than that of the ceramic body 110. In such case, the portions of the wafer located over the pin holes 112 may be heated relatively quickly by the heat transfer members 150. Alternatively, the heat transfer members 150 may be made of the same material as the ceramic body 110.

Meanwhile, the heat transfer members 150 may have various shapes.

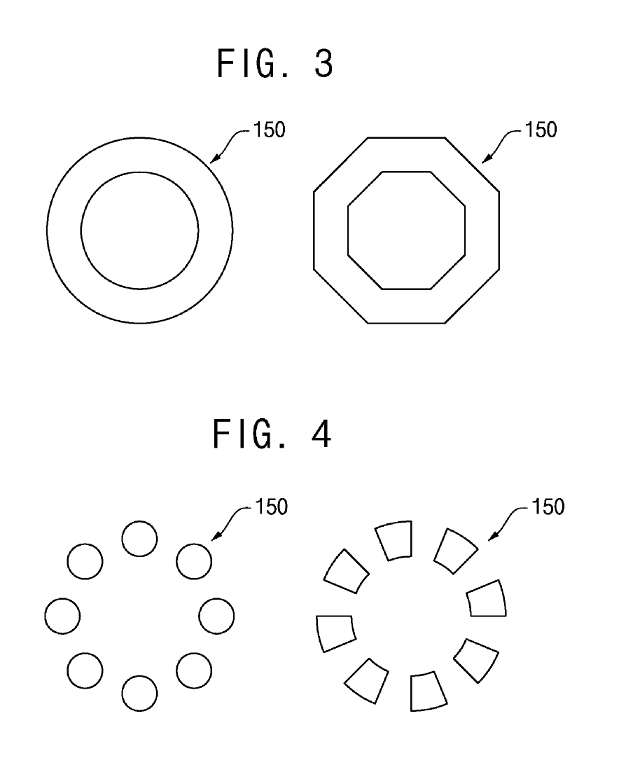

FIG. 3 is a plan view illustrating some examples of the heat transfer members as shown in FIG. 1.

Referring to FIG. 3, the heat transfer members 150 may have a ring shape configured to surround the upper portions of the pin holes 112, respectively. For example, each of the heat transfer members 150 may have a circular ring or a polygonal ring shape as shown in FIG. 3. Further, though not shown in figures, inner and outer surfaces of the heat transfer members 150 may have a wrinkle shape or an uneven shape.

FIG. 4 is a plan view illustrating other examples of the heat transfer members as shown in FIG. 1.

Referring to FIG. 4, each of the heat transfer members 150 may include a plurality of parts disposed to be spaced apart from each other around the respective pin holes 112. For example, the heat transfer parts may have various shapes such as a circular shape, a polygonal shape, and the like.

Referring again to FIGS. 1 and 2, the heat transfer members 150 may be disposed in close contact with the pin holes 112 or may be spaced apart from the pin holes 112. For example, when the heat transfer members 150 have a circular ring shape, an inner radius of the heat transfer members 150 may be substantially equal to or greater than an uppermost radius of the pin holes 112. For example, a distance G between the each of the heat transfer members 150 and the each of the upper portions of the pin holes 112 may be 0 to approximately 20 mm.

On the other hand, when the inner radius of the heat transfer members 150 is smaller than the uppermost radius of the pin holes 112, the heat transfer members 150 may interfere with the vertical movement of the lift pins. Further, when the distance G between the heat transfer members 150 and the upper portion of the pin holes 112 is greater than approximately 20 mm, the heat generated from the heating member 130 may not be sufficiently transferred to the portions of the wafer located over the pin holes 112.

An upper surface area of the each of the heat transfer members 150 may be approximately 13 mm² to approximately 1900 mm². When the upper surface area of the heat transfer members 150 is less than approximately 13 mm², the heat generated from the heating member 130 may not be sufficiently transferred to the portions of the wafer located over the pin holes 112. Thus, the temperature of the portions of the wafer located over the pin holes 112 may be relatively lower than that of the remaining portions.

Further, when the upper surface area of the heat transfer members 150 is greater than approximately 1900 mm², the heat generated from the heating member 130 may be excessively transferred to the portions of the wafer located over the pin holes 112. Thus, the temperature of the portions of the wafer located over the pin holes 112 may be relatively higher than that of the remaining portions.

The heat transfer members 150 may have a same height as the support members 120. When the height of the heat transfer members 150 is lower than that of the support members 120, the portions of the wafer located over the pin holes 112 may be spaced apart from the heat transfer members 150, and the temperature of the portions of the wafer located over the pin holes 112 may be relatively lower than that of the remaining portions. On the contrary, when the height of the heat transfer members 150 is higher than that of the support members 120, the temperature of the portions of the wafer located over the pin holes 112 may be relatively higher than that of the remaining portions.

For example, the height of the heat transfer members 150 may be approximately 5 μm to approximately 40 μm. When the height of the heat transfer members 150 is less than approximately 5 μm, it is difficult to manufacture the heat transfer members 150. When the height of the heat transfer members 150 exceeds approximately 40 μm, the heat generated from the heating member 130 may not be sufficiently transferred to the portions of the wafer located over the pin holes 112 due to heat loss.

### Experimental Example 1

TABLE 1

| Distance between pin | Temperature | |
|---|---|---|
| hole and heat transfer | difference | |
| member (mm) | (° C.) | Uniformity |
| 0 | 4.0~4.8 | Uniform |
| 5 | 2.5~3.2 | Uniform |
| 10 | 1.2~1.9 | Uniform |
| 15 | 0.9~4.8 | Uniform |
| 20 | 3.4~5.2 | Uniform |
| 25 | 6.5~9.4 | Non-uniform |

In an experimental example 1, after a wafer was placed on a ceramic heater 100, the ceramic heater 100 was heated to 700° C. by using a heater member 130. The temperatures of portions of the wafer located over pin holes 112 and the remaining portions were measured while the distance between the pin holes 112 and heat transfer members 150 was increased by 5 mm. At this time, heat transfer members 150 having a circular ring shape were used, and an upper surface area of the heat transfer members 150 remained constant. In the experimental example 1, when the temperature difference between the portions of the wafer located over the pin holes 112 and the remaining portions was less than 8° C., the temperature of the wafer was judged to be uniform.

Referring to Table 1, when the distance between the pin holes 112 and the heat transfer members 150 was in a range of 0 to 20 mm, the temperature of the wafer was measured to be uniform, and when the distance between the pin holes 112 and the heat transfer members 150 was 25 mm, the temperature of the wafer was measured to be non-uniform. Thus, the distance between the pin holes 112 and the heat transfer members 150 may be preferably determined in a range of 0 to approximately 20 mm in order to uniformly heat the wafer.

### Experimental Example 2

TABLE 2

| Height of | Temperature | |
|---|---|---|
| heat transfer | difference | |
| member (μm) | (° C.) | Uniformity |
| 40~45 | 8.5~11.0 | Non-uniform |
| 35~39 | 7.2~7.8 | Uniform |
| 30~34 | 6.8~7.4 | Uniform |

In an experimental example 2, after a wafer was placed on a ceramic heater 100, the ceramic heater 100 was heated to 700° C. by using a heater member 130. The temperatures of portions of the wafer located over pin holes 112 and the remaining portions were measured while changing the height of the heat transfer members 150. At this time, heat transfer members 150 having a circular ring shape were used, and an upper surface area of the heat transfer members 150 remained constant. In the experimental example 2, when the temperature difference between the portions of the wafer located over the pin holes 112 and the remaining portions was less than 8° C., the temperature of the wafer was judged to be uniform.

Referring to Table 2, when the height of the heat transfer members 150 was in a range of 30 μm to 39 μm, the temperature of the wafer was measured to be uniform, and when the height of the heat transfer members 150 was in a range of 40 μm to 45 μm, the temperature of the wafer was measured to be non-uniform. Thus, the height of the heat transfer members 150 may be preferably determined to be lower than approximately 40 μm in order to uniformly heat the wafer.

In accordance with the exemplary embodiments of the present disclosure as described above, a ceramic heater 100 may include heat transfer members 150 disposed on an upper surface of a ceramic body 110 to surround upper portions of pin holes 112. Thus, even if a heating member 130 is spaced apart from the pin holes 112 in the ceramic body 110 and the upper portions of the pin holes 112 have a structure in which a cross-sectional area increases upward, the heat generated from the heating member 130 may be directly transferred to portions of a wafer located over the pin holes 112 through the heat transfer members 150. Consequently, the wafer may be uniformly heated by the heating member 130, and thus a layer may be uniformly formed on the wafer during a deposition process.

Although the ceramic heater 100 has been described with reference to specific embodiments, it is not limited thereto. Therefore, it will be readily understood by those skilled in the art that various modifications and changes can be made thereto without departing from the spirit and scope of the present disclosure defined by the appended claims.

1. A ceramic heater comprising:
a ceramic body having a plurality of pin holes for a vertical movement of lift pins, the pin holes being configured to pass through the ceramic body;
a heating member disposed inside the ceramic body to heat a wafer which is placed on the ceramic body; and
heat transfer members disposed on an upper surface of the ceramic body to surround upper portions of the pin holes, respectively, wherein the heat transfer members transfer heat generated from the heating member so as to the wafer to uniformly heat the wafer.

2. The ceramic heater of claim 1, wherein the heat transfer members are made of a same material as the ceramic body or a material having a heat transfer rate higher than the ceramic body.

3. The ceramic heater of claim 1, wherein the heat transfer members have a ring shape configured to surround the upper portions of the pin holes, respectively.

4. The ceramic heater of claim 1, wherein each of the heat transfer members comprises a plurality of parts disposed to be spaced apart from each other around the respective pin holes.

5. The ceramic heater of claim 1, wherein the heat transfer members are disposed in close contact with the pin holes or spaced apart from the pin holes.

6. The ceramic heater of claim 5, wherein a distance between each of the heat transfer members and each of the pin holes is 0 to approximately 20 mm.

7. The ceramic heater of claim 1, wherein an upper surface area of each of the heat transfer members is approximately 13 mm² to approximately 1900 mm².

8. The ceramic heater of claim 1, further comprising a plurality of support members disposed on the upper surface of the ceramic body to support the wafer.

9. The ceramic heater of claim 8, wherein the heat transfer members have a same height as the support members.

10. The ceramic heater of claim 9, wherein the height of the heat transfer members is approximately 5 μm to approximately 40 μm.

11. The ceramic heater of claim 1, further comprising an electrode member disposed inside the ceramic body and electrically connected with an external ground member.
